(19) United States
(12) Patent Application Publication
(10) Pub. No.: US 2024/0426927 A1
(43) Pub. Date: Dec. 26, 2024

(54) METHOD AND APPARATUS FOR DIAGNOSING BATTERY CELL

(71) Applicant: LG ENERGY SOLUTION, LTD., Seoul (KR)

(72) Inventors: Chulmin JEON, Daejeon (KR); Bomjin LEE, Daejeon (KR); Du Seong YOON, Daejeon (KR)

(73) Assignee: LG ENERGY SOLUTION, LTD., Seoul (KR)

(21) Appl. No.: 18/687,672

(22) PCT Filed: Nov. 21, 2022
(86) PCT No.: PCT/KR2022/018432

§ 371 Date: Feb. 28, 2024

(30) Foreign Application Priority Data
Dec. 8, 2021 (KR) 10-2021-0174607

(51) Int. Cl. G01R 31/389; G01R 31/396

(52) U.S. Cl. CPC G01R 31/389; G01R 31/396

(57) ABSTRACT

Discussed are a method and an apparatus for diagnosing a battery cell. The method may include applying, by the apparatus for diagnosing the battery cell, an activation waveform having a predetermined frequency to the battery cell in an activation process, and performing an electrochemical impedance spectroscopy (EIS) measurement in a charging section of the activation process. The method may further include, based on the EIS measurement, calculating a slope of a reactance of the battery cell in a voltage section of a predetermined range, and diagnosing the battery cell based on the slope.

### CROSS-REFERENCE TO RELATED APPLICATION

This application claims priority to and the benefit of Korean Patent Application No. 10-2021-0174607 filed in the Korean Intellectual Property Office on Dec. 8, 2021, the entire contents of which are incorporated herein by reference.

### TECHNICAL FIELD

The present invention relates to a method and an apparatus for diagnosing a battery cell.

### BACKGROUND ART

An electric vehicle or hybrid vehicle is a vehicle that generally obtains power by driving a motor by using a battery as a power source, and research is being actively conducted in that the electric vehicle is an alternative capable of solving the pollution and energy problems of internal combustion vehicles. In addition, rechargeable batteries are used in various external devices other than electric vehicles.

Among batteries, in the case of a lithium battery which uses lithium ions in a redox reaction, lithium may be precipitated on the electrode depending on the usage environment of charging and discharging. Since lithium precipitation is one of the direct causes of battery ignition problems, a diagnosis method for detecting lithium precipitation is required. In particular, since it is difficult to detect lithium precipitation after manufacturing and selling batteries, a diagnosis method for detecting lithium precipitation during a battery production process is required.

### DISCLOSURE

### Technical Problem

Certain example embodiments of the present invention may provide a method and an apparatus for diagnosing a battery cell capable of detecting lithium precipitation in an activation process.

### Technical Solution

An example embodiment of the present invention may provide a method of diagnosing a battery cell. The method may include: applying an activation waveform having a predetermined frequency to the battery cell in an activation process; performing an electrochemical impedance spectroscopy (EIS) measurement in a charging section of the activation process; based on the EIS measurement, calculating a slope of a reactance of the battery cell in a voltage section of a predetermined range; and diagnosing the battery cell based on the slope.

Another example embodiment of the present invention may provide an apparatus for diagnosing a battery cell. The apparatus may include a charger/discharger, an EIS meter, and a processor. The charger/discharger may be configured to apply an activation waveform having a predetermined frequency to the battery cell in an activation process, and the EIS meter may be configured to perform EIS measurement in a charging section of the activation process. The processor may be configured to calculate a slope of a reactance of the battery cell in a voltage section of a predetermined range based on the EIS measurement, and diagnose the battery cell based on the slope. In some example embodiments, the apparatus may further include a memory configured to store information on a reactance slope of a normal cell and a reactance slope of a defective cell for each frequency. The processor may obtain information on the reactance slope of the normal cell and the reactance slope of the defective cell corresponding to the predetermined frequency from the memory, diagnose the battery cell as a normal cell when the reactance slope in the voltage section of the predetermined range is included in the reactance slope of the normal cell, and diagnose the battery cell as a defective cell when the reactance slope in the voltage section of the predetermined range is included in the reactance slope of the defective cell.

Still another example embodiment of the present invention may provide a computer program stored in a non-volatile recording medium and can be executed by a computing device. When, executed by the computing device, the computer program may cause the computing device to execute a method comprising an operation of calculating a slope of a reactance of a battery cell in a voltage section of a predetermined range based on an electrochemical impedance spectroscopy (EIS) measurement performed in a charging section of an activation process for applying an activation waveform with a predetermined frequency to the battery cell, and an operation of diagnosing the battery cell based on the slope.

In example embodiments, the diagnosing of the battery cell may include diagnosing the battery cell as a defective cell when the slope is equal to or less than a threshold value.

In example embodiments, the threshold value may be −8.2.

In example embodiments, the threshold value may be −8.

In example embodiments, the predetermined frequency may be equal to or less than 25 Hz.

In example embodiments, the predetermined frequency may be equal to or greater than 1 Hz and equal to or less than 25 Hz.

In example embodiments, the voltage section may include a section between 3.5V and 3.8V.

### Advantageous Effects

According to the example embodiment, it is possible to diagnose a defective cell in which lithium precipitation has occurred based on a reactance slope.

### DESCRIPTION OF THE DRAWINGS

FIG. 1 is a diagram illustrating an example of a battery diagnosis apparatus according to an example embodiment of the present invention.

FIGS. 2, 3, 4, 5, 6, 7, 8, 9, 10, 11, 12, 13, 14, 15, 16, 17, 18, and 19 are respectively diagrams illustrating results of analyzing voltage and reactance of a battery cell measured in a charging section of an activation process while changing a frequency of an activation waveform.

FIG. 20 is a flowchart illustrating an example of a diagnosis method of the battery diagnosis apparatus according to an example embodiment of the present invention.

### MODE FOR INVENTION

In the following detailed description, only certain example embodiments of the present invention have been illustrated and described, simply by way of illustration. As those skilled in the art would realize, the described example embodiments may be modified in various different ways, all without departing from the spirit or scope of the present invention. Accordingly, the drawings and description are to be regarded as illustrative in nature and not restrictive. Like reference numerals designate like elements throughout the specification.

It should be understood that when one constituent element is referred to as being “coupled to” or “connected to” another constituent element, one constituent element can be directly coupled to or connected to the other constituent element, but intervening elements may also be present. By contrast, when one constituent element is referred to as being “directly coupled to” or “directly connected to” another constituent element, it should be understood that there are no intervening elements.

Expressions written in the singular in the following description may be interpreted in the singular or plural unless explicit expressions, such as “one” or “single”, are used.

In the flowchart described with reference to the drawing, the order of operations may be changed, several operations may be merged, some operations may be divided, and specific operations may not be performed.

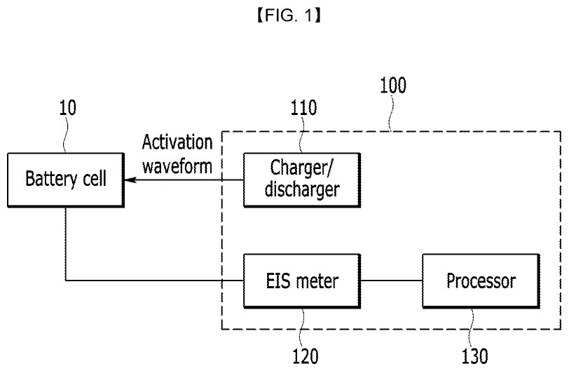

FIG. 1 is a diagram illustrating an example of a battery diagnosis apparatus according to an example embodiment of the present invention.

A battery diagnosis apparatus 100 is connected to battery cells 10 and diagnoses defective cells in which lithium precipitation occurs among the battery cells 10. In some example embodiments, the battery diagnosis apparatus 100 may be connected to the plurality of battery cells 10 to diagnose the plurality of battery cells 10. In some example embodiments, the battery cell 10 may be, for example, a lithium battery, such as a lithium ion battery or a lithium ion polymer battery.

The battery diagnosis apparatus 100 includes a charger/discharger 110, an electrochemical impedance spectroscopy (EIS) meter 120, and a processor 130. In some example embodiments, the processor 130 may be provided as a computing device.

In some example embodiments, the battery cell 10 may be manufactured by injecting an electrolyte into an electrode assembly including a negative electrode, a positive electrode, and a separator. Such a battery cell 10 may function as a battery by activation through charging and discharging, and this process is referred to as an activation process. The charger/discharger 110 may charge or discharge the battery cell 10 by applying an activation waveform to the battery cell 10 in the activation process. The activation waveform may be an AC potential having a predetermined frequency. In some example embodiments, the charger/discharger 110 may apply an activation waveform to the positive electrode terminal of the battery cell 10 in the state where a negative electrode terminal of the battery cell 10 is connected to a ground terminal. In some example embodiments, the charger/discharger 110 includes a plurality of channels to which the plurality of battery cells 10 is respectively connected, and may apply an activation waveform to each of the plurality of channels to charge or discharge the plurality of battery cells 10.

The EIS meter 120 performs EIS measurement on the battery cell 10 while the battery cell 10 is being charged or discharged. In some example embodiments, the EIS meter 120 may perform in-situ EIS measurements. The EIS meter 120 measures the response of the battery cell 10 while applying the activation waveform, and measures an imaginary component of impedance of the battery cell 10, that is, reactance based on the activation waveform and the response of the battery cell 10. In some example embodiments, the EIS meter 120 may measure an AC current response (that is, output current) of the battery cell 10 while applying the activation waveform (AC potential), and measure reactance of the battery cell 10 based on the AC potential and the output current. In some example embodiments, the EIS meter 120 may measure the reactance of the battery cell 10 by determining the phase shift and amplitude change of the output current based on the AC current response. Also, the EIS meter 120 may measure the voltage (that is, charging voltage) of the battery cell 10 in the charging section of the battery cell 10 while applying the activation waveform.

The processor 130 calculates a slope (change) of the reactance in a voltage section of a predetermined range based on the measurement result of the EIS meter 120, and diagnoses whether the battery cell 10 is a defective cell or a normal cell based on the slope of the reactance. In some example embodiments, the processor 130 may diagnose whether the battery cell 10 is a defective cell or a normal cell based on the slope of the reactance of the battery cell 10 according to the voltage of the battery cell 10 in a voltage section of a predetermined range among the voltages of the battery cell 10 in the charging section. In some example embodiments, when the reactance slope of the battery cell 10 according to the increase in voltage of the battery cell 10 is equal to or less than a threshold value in the voltage section of the predetermined range, the processor 130 may diagnose the corresponding battery cell 10 as a defective cell.

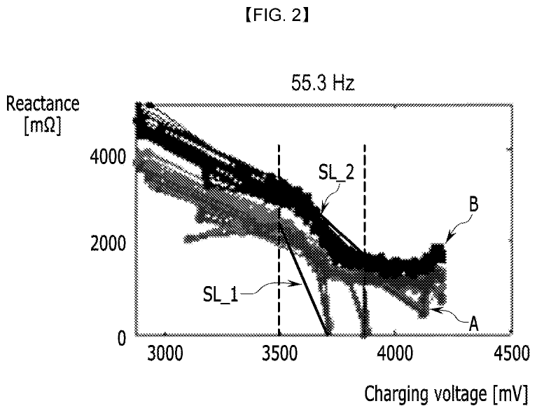

Next, a predetermined frequency and a voltage section of a predetermined range used in the battery diagnosis apparatus according to the example embodiment of the present invention will be described with reference to FIGS. 2 to 19.

FIGS. 2, 3, 4, 5, 6, 7, 8, 9, 10, 11, 12, 13, 14, 15, 16, 17, 18, and 19 are respectively diagrams illustrating results of analyzing voltage and reactance of a battery cell measured in a charging section of an activation process while changing a frequency of an activation waveform. In FIGS. 2 to 19, the horizontal axis represents voltage [mV] and the vertical axis represents reactance [mΩ].

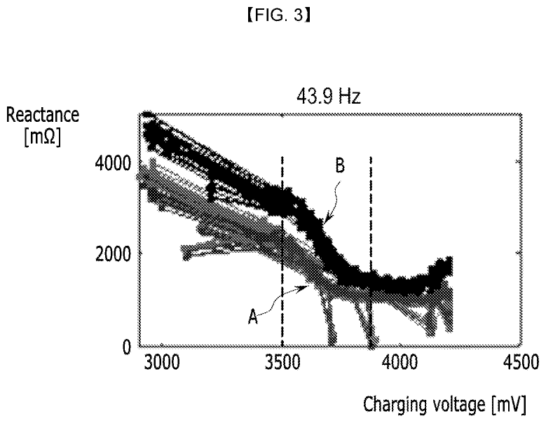

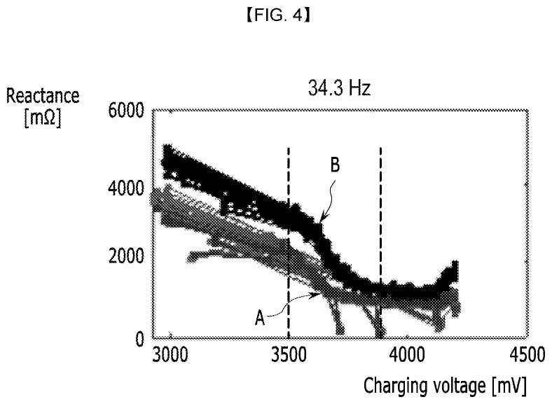

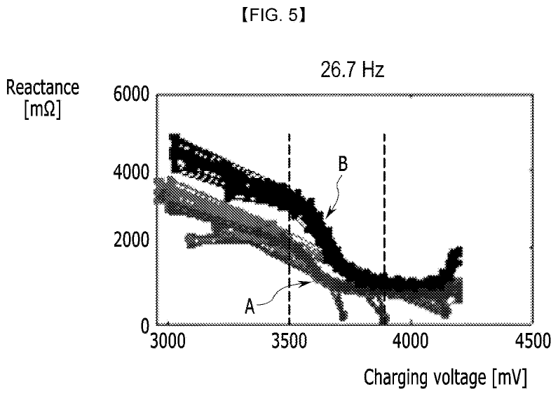

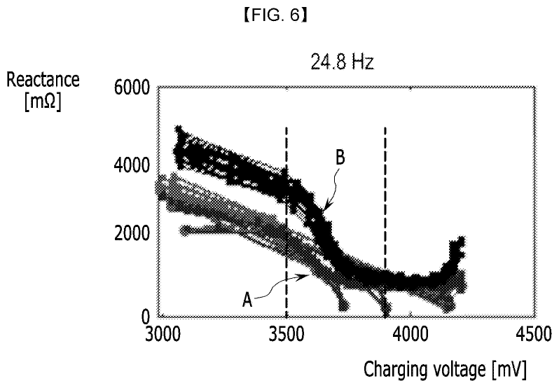

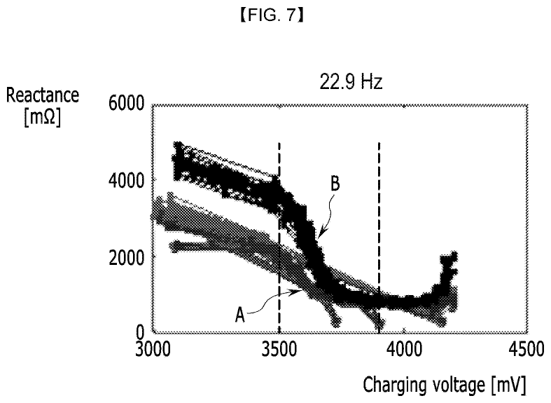

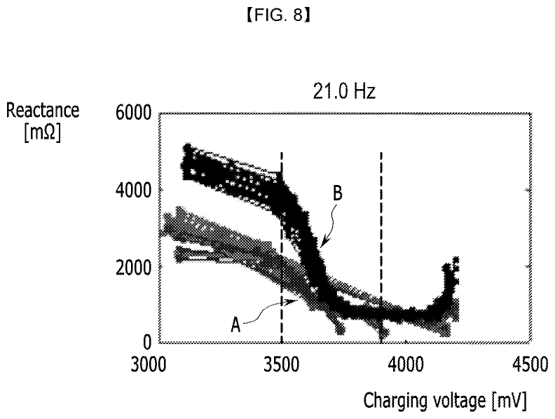

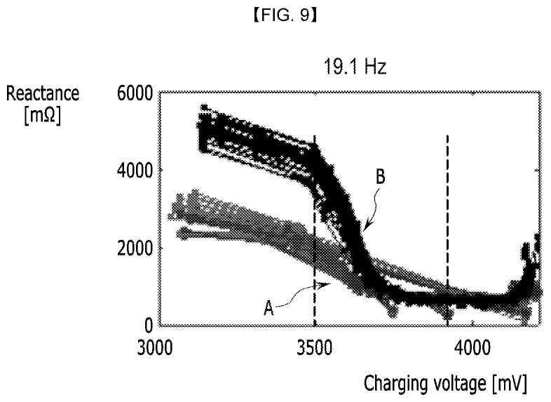

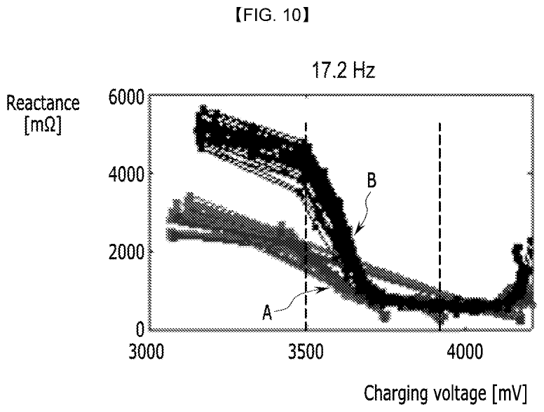

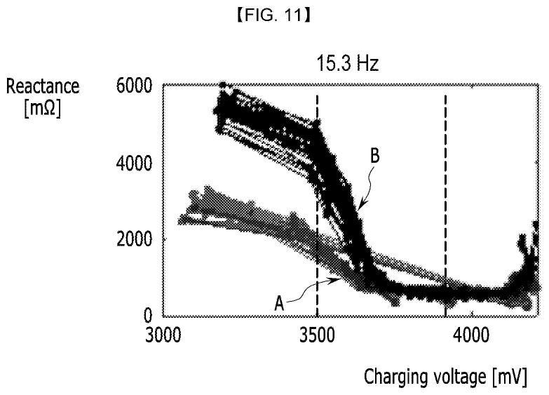

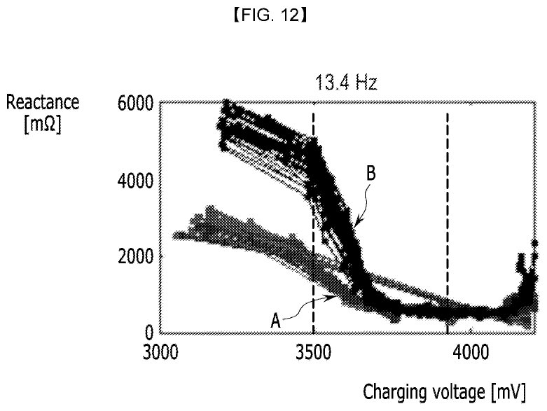

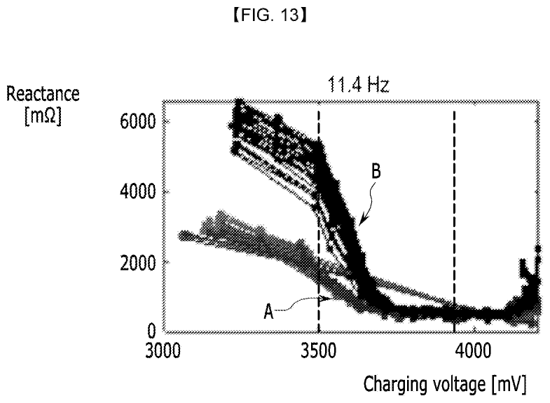

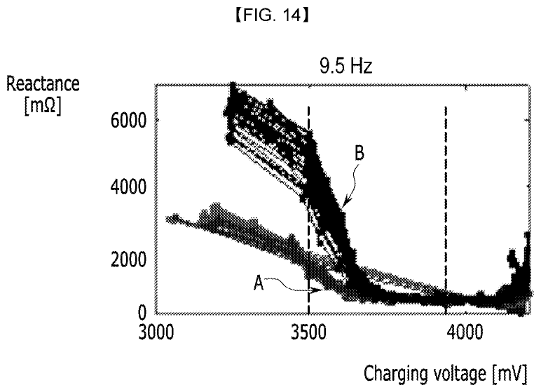

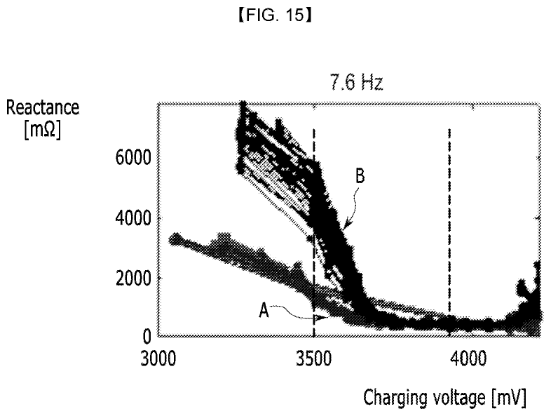

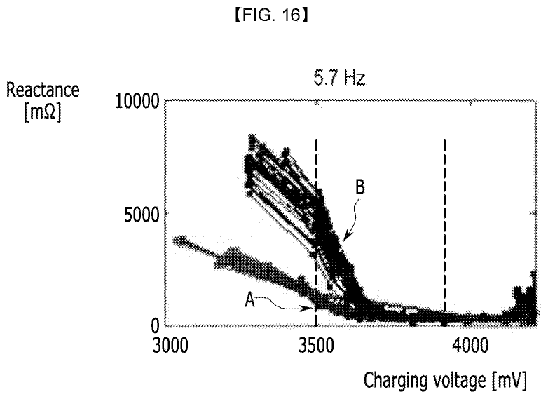

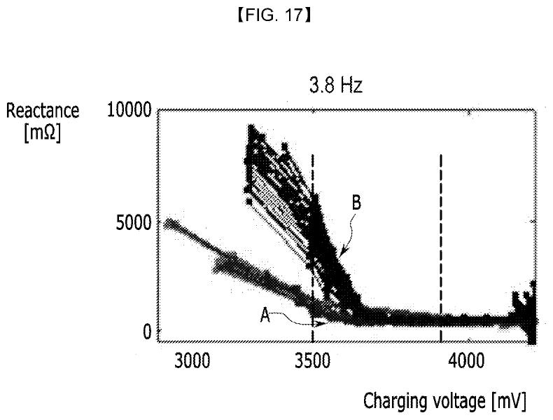

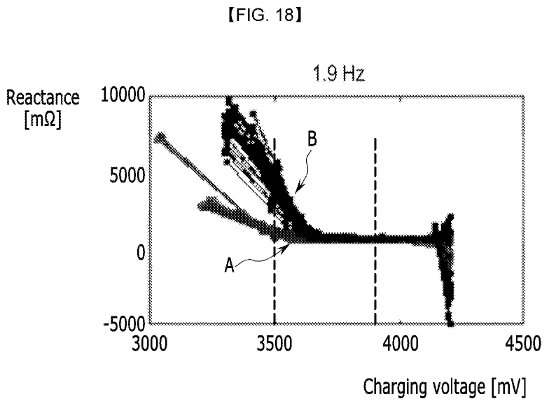

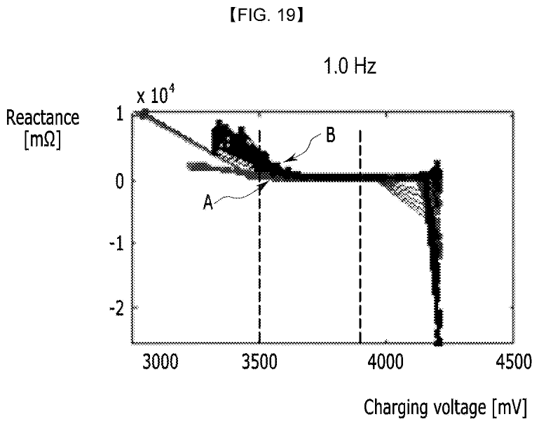

FIG. 2 illustrates a case where the frequency is 55.3 Hz, FIG. 3 illustrates a case where the frequency is 43.9 Hz, FIG. 4 illustrates a case where the frequency is 34.3 Hz, FIG. 5 illustrates a case where the frequency is 26.7 Hz, FIG. 6 illustrates a case where the frequency is 24.8 Hz, FIG. 7 illustrates a case where the frequency is 22.9 Hz, FIG. 8 illustrates a case where the frequency is 21.0 Hz, FIG. 9 illustrates a case where the frequency is 19.1 Hz, FIG. 10 illustrates a case where the frequency is 17.2 Hz, FIG. 11 illustrates a case where the frequency is 15.3 Hz, FIG. 12 illustrates a case where the frequency is 13.4 Hz, FIG. 13 illustrates a case where the frequency is 11.4 Hz, FIG. 14 illustrates a case where the frequency is 9.5 Hz, FIG. 15 illustrates a case where the frequency is 7.6 Hz, FIG. 16 illustrates a case where the frequency is 5.7 Hz, FIG. 17 illustrates a case where the frequency is 3.8 Hz, FIG. 18 illustrates a case where the frequency is 1.9 Hz, and FIG. 19 illustrates a case where the frequency is 1.0 Hz.

In each of FIGS. 2 to 19, a first group A is a group of reactance graphs for each of a plurality of normal cells, and a second group B is a group of reactance graphs for each of a plurality of defective cells. In each of FIGS. 2 to 19, reactance graphs for each of a plurality of normal cells and a plurality of defective cells overlap each other in some sections. That is, graphs may be difficult to be distinguished from each other in some sections. However, the first group A may be distinguished by light gray and the second group B may be distinguished by black. Meanwhile, although the boundary between the first group A and the second group B may be unclear in some voltage sections, data required in the present invention are disclosed in Table 1 below.

According to the example embodiment, in the charging voltage section between 3.5V and 3.8V illustrated in FIGS. 2 to 19, a reactance slope for a predetermined battery cell 10 may be calculated based on a difference value between a first reactance value corresponding to 3.5V and a second reactance value corresponding to 3.8V. That is, even though the reactance value exhibits the form of the graph increasing or decreasing more than the first reactance value or the second reactance value in the charging voltage section between 3.5V and 3.8V, the reactance slope may be calculated based on the first reactance value and the second reactance value. However, the present invention is not limited thereto, and according to various example embodiments, a reactance slope may be calculated in the charging voltage section between 3.5V and 3.8V.

Referring to FIG. 2, ‘SL_1’ may be a reactance slope for a normal cell, and SL_2′ may be a reactance slope for a defective cell. Also, the reactance slope SL_1 or SL_2 may be graphs corresponding to a maximum value among a plurality of reactance slopes corresponding to the first group A or the second group B. However, the present invention is not limited thereto, and the reactance slopes SL_1 or SL_2 may indicate a minimum value or an average value among a plurality of reactance slopes corresponding to the first group A or the second group B.

Referring to FIGS. 2 to 19, in the case of a defective cell, it can be seen that the reactance rapidly decreases as the charging voltage increases in the voltage section of a predetermined range. In particular, it can be seen that when an activation waveform having a predetermined frequency is used, the reactance slope of the defective cell according to the increase in the charging voltage is distinguished from the reactance slope of the normal cell.

As illustrated in FIGS. 2 to 19, it can be seen that the magnitude (absolute value) of the reactance slope in the section where the charging voltage is 3.5V or more and 3.8V or less is greater than the magnitude of the reactance slope in other charging voltage sections. In addition, as illustrated in FIGS. 6 to 19, it can be seen that when an activation waveform having a frequency of 1 Hz or more and 25 Hz or less is used, the magnitude of the reactance slope of the defective cell is significantly larger than that of the normal cell to a distinguishable extent.

On the other hand, as illustrated in FIGS. 2 to 5 and 19, it can be seen that when an activation waveform having a frequency higher than 25 Hz is used, it is difficult to compare the magnitude of the reactance slope of a defective cell with the magnitude of the reactance slope of a normal cell.

Specifically, when the reactance slope in the charging voltage section between 3.5V and 3.8V illustrated in FIGS. 2 to 19 is digitized, the result is given as represented in Table 1. As shown in Table 1, the information on the reactance slope of each normal cell and the reactance slope of a defective cell for each frequency may be stored in a memory (not illustrated) of the battery diagnosis apparatus (reference numeral 100 in FIG. 1).

Since the reactance slope of the battery cell may change depending on the state of the battery cell, Table 1 shows the maximum value, minimum value, and average value of the reactance slope. Specifically, Table 1 shows the maximum value, minimum value, and average value among the plurality of reactance slopes belonging to the first group A for each frequency of the activation waveform. Further, Table 1 shows the maximum value, minimum value, and average value among the plurality of reactance slopes belonging to the second group B for each frequency of the activation waveform. In this case, the first group A is a group of reactance graphs for each of a plurality of normal cells, and the second group B is a group of reactance graphs for each of a plurality of defective cells.

### Table

Referring to Table 1, when the frequency of the activation waveform is greater than 25 Hz, since the section of the reactance slope of the defective cell partially overlaps the section of the reactance slope of the normal cell, it may be difficult to distinguish the reactance slope of the defective cell from the normal cell. For example, when the frequency of the activation waveform is 55.3 Hz, the reactance slope of the defective cell has a value between −6.03 and −5.00, and the reactance slope of the normal cell has a value between −6.85 and −3.26. Accordingly, when a reactance slope of a certain battery cell is measured as −6.00, it cannot be distinguished whether the corresponding battery cell is a normal cell or a defective cell. Similarly, when the frequency of the activation waveform is 26.7 Hz, the reactance slope of the defective cell has a value between −9.40 and −7.51, and the reactance slope of the normal cell has a value between −7.54 and-2.40. Accordingly, when a reactance slope of a certain battery cell is measured as −7.52, it cannot be distinguished whether the corresponding battery cell is a normal cell or a defective cell.

However, when the frequency of the activation waveform is equal to or less than 25 Hz, since the section of the reactance slope of the defective cell and the section of the reactance slope of the normal cell do not overlap, the reactance slope of a defective cell and the reactance slope of a normal cell may be distinguished. For example, when the frequency of the activation waveform is 24.8 Hz, the reactance slope of the defective cell has a value between −10.86 and −8.20, and the reactance slope of a normal cell has a value between −6.91 and −2.45, so when a reactance slope of a certain battery cell is measured as a value of −8.20 or less, the corresponding battery cell may be determined to be a defective cell. Similarly, if the frequency of the activation waveform is 1.0 Hz, 1.9 Hz, 3.6 Hz, 5.7 Hz, 7.6 Hz, 9.5 Hz, 11.4 Hz, 13.4 Hz, 15.3 Hz, 17.2 Hz, 19.1 Hz, 21 Hz, or 22.9 Hz, since the section of the reactance slope of the defective cell and the section of the reactance slope of the normal cell do not overlap, a normal cell and a defective cell may be distinguished by the reactance slope.

TABLE 1

| | Defective cell | | | Normal cell | | |
|---|---|---|---|---|---|---|
| | (second group, B) | | | (first group, A) | | |
| fre- | Mini- | Maxi- | | Mini- | Maxi- | |
| quency[Hz] | mum | mum | average | mum | mum | average |
| 55.3 | −6.03 | −5.00 | −5.51 | −6.85 | −3.26 | −4.57 |
| 43.9 | −7.02 | −5.71 | −6.38 | −6.81 | −2.27 | −4.60 |
| 34.3 | −8.36 | −6.55 | −7.32 | −6.98 | −1.72 | −4.55 |
| 26.7 | −9.40 | −7.51 | −8.48 | −7.54 | −2.40 | −4.42 |
| 24.8 | −10.86 | −8.20 | −9.69 | −6.91 | −2.45 | −4.38 |
| 22.9 | −12.47 | −8.92 | −10.98 | −6.81 | −1.79 | −4.33 |
| 21.0 | −14.76 | −9.40 | −12.19 | −6.39 | −1.37 | −4.15 |
| 19.1 | −16.37 | −9.37 | −13.14 | −6.56 | −0.39 | −4.10 |
| 17.2 | −16.73 | −8.76 | −13.40 | −6.42 | −0.67 | −3.92 |
| 15.3 | −16.80 | −8.66 | −13.56 | −5.84 | 0.16 | −3.75 |
| 13.4 | −19.19 | −8.58 | −13.90 | −6.27 | −0.78 | −3.54 |
| 11.4 | −19.87 | −7.83 | −14.44 | −5.89 | −1.24 | −3.30 |
| 9.5 | −21.34 | −7.52 | −14.75 | −5.43 | 0.28 | −3.02 |
| 7.6 | −22.05 | −6.61 | −14.97 | −4.78 | 0.16 | −2.70 |
| 5.7 | −22.63 | −5.92 | −14.53 | −3.87 | −0.13 | −2.23 |
| 3.6 | −21.63 | −4.92 | −13.69 | −3.27 | 0.40 | −1.58 |
| 1.9 | −19.53 | −3.46 | −11.89 | −1.74 | 0.71 | −0.97 |
| 1.0 | −13.49 | −2.03 | −8.24 | −1.59 | 1.04 | −0.30 |

As described above, when the frequency of the activation waveform is 25 Hz or less, normal cells and defective cells may be distinguished by the reactance slope in the charging voltage section between 3.5V and 3.8V. In particular, as shown in Table 1, when the frequency of the activation waveform is 25 Hz or less, since the smallest value among the maximum values of the reactance slope in the charging voltage section between 3.5V and 3.8V is −8.2,in some example embodiments, a discharge cell having a reactance slope of −8.2, that is, a threshold value, or less may be determined as a defective cell. By setting the smallest value among the maximum values of the reactance slope as the threshold value, it is possible to prevent a normal cell from being determined as a defective cell.

In some example embodiments, since the minimum value of the reactance slope of a normal cell at 24.8 Hz is −6.91, the threshold value may be set to −8 that is greater than −8.2 in consideration of measurement error.

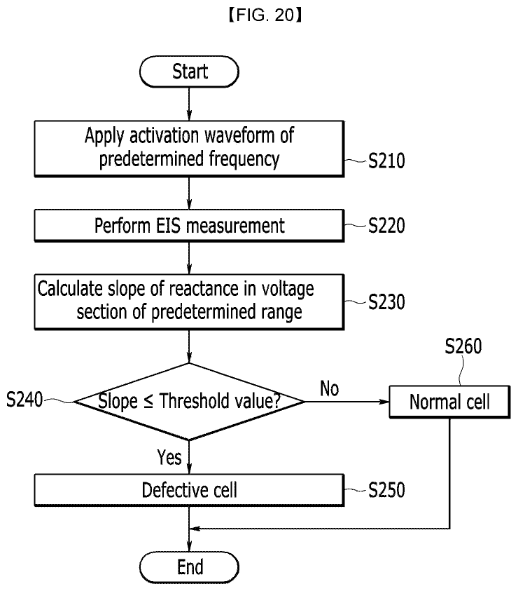

FIG. 20 is a flowchart illustrating an example of a diagnosis method of the battery diagnosis apparatus according to an example embodiment of the present invention.

Referring to FIG. 20, the battery diagnosis apparatus performs an activation process by applying an activation waveform having a predetermined frequency to a battery cell (S210). In some example embodiments, the predetermined frequency may be less than 25 Hz. In some example embodiments, the predetermined frequency may be equal to or greater than 1 Hz and equal to or less than 25 Hz. The battery diagnosis apparatus measures reactance and a charging voltage of the battery cell by performing EIS measurement on the battery cell in the charging section of the activation process (S220).

The battery diagnosis apparatus calculates a reactance slope of the battery cell according to the voltage of the battery cell in a charging voltage section of a predetermined range (S230). In some example embodiments, the charging voltage section of the predetermined range may be equal to or greater than −3.5V and equal to or less than −3.8V. The battery diagnosis apparatus compares the reactance slope with a threshold value (S240), and diagnoses the corresponding battery cell as a defective cell when the reactance slope is equal to or less than the threshold value (S250). In some example embodiments, the battery diagnosis apparatus may diagnose a corresponding battery cell as a defective cell in which lithium precipitation occurs. When the reactance slope is greater than the threshold value, the battery diagnosis apparatus diagnoses the corresponding battery cell as a normal cell (S260). In some example embodiments, the threshold value may be −8. In some example embodiments, the threshold value may be −8.2.

In some example embodiments, the battery diagnosis apparatus may obtain information on the reactance slopes of normal cells and the reactance slopes of defective cells corresponding to a predetermined frequency from a memory, and compare the calculated reactance slope may with the reactance slope obtained from the memory (S240). The battery diagnosis apparatus may diagnose the battery cell as a defective cell when the calculated reactance slope is included in the reactance slope of the defective cell (S250). The battery diagnosis apparatus may diagnose the battery cell as a normal cell when the calculated reactance slope is included in the reactance slope of the normal cell (S260).

According to the example embodiment described above, it is possible to diagnose a defective cell in which lithium precipitation has occurred based on a reactance slope.

In some example embodiments, a computing device (or processor) may perform operations on a computer program for executing the diagnostic method described above. The computer program for executing the diagnostic method may be loaded into memory. The computer program may include instructions that cause the computing device to perform the diagnosis method when loaded into memory. In some example embodiments, the computer program may cause the computing device to execute an operation of calculating a reactance slope of the battery cell in a voltage section of a predetermined range and an operation of diagnosing the battery cell based on the slope based on the EIS measurement performed in the charging section of the activation process for applying an activation waveform having a predetermined frequency to the battery cell.

Although an example embodiment of the present invention has been described in detail, the scope of the present invention is not limited by the example embodiment. Various changes and modifications using the basic concept of the present invention defined in the accompanying claims by those skilled in the art shall be construed to belong to the scope of the present invention.

1. A method of diagnosing a battery cell, the method comprising:
applying an activation waveform having a predetermined frequency to the battery cell in an activation process;
performing an electrochemical impedance spectroscopy (EIS) measurement in a charging section of the activation process;
based on the EIS measurement, calculating a slope of a reactance of the battery cell in a voltage section of a predetermined range; and
diagnosing the battery cell based on the slope.

2. The method of claim 1, wherein the diagnosing of the battery cell includes diagnosing the battery cell as a defective cell when the slope is equal to or less than a threshold value.

3. The method of claim 2, wherein the threshold value is −8.2.

4. The method of claim 2, wherein the threshold value is −8.

5. The method of claim 1, wherein the predetermined frequency is equal to or less than 25 Hz.

6. The method of claim 5, wherein the predetermined frequency is equal to or greater than 1 Hz.

7. The method of claim 1, wherein the voltage section includes a section between 3.5V and 3.8V.

8. An apparatus for diagnosing a battery cell, the apparatus comprising:
a charger/discharger configured to apply an activation waveform having a predetermined frequency to the battery cell in an activation process;
an electrochemical impedance spectroscopy (EIS) meter configured to perform an EIS measurement in a charging section of the activation process; and
a processor configured to calculate a slope of a reactance of the battery cell in a voltage section of a predetermined range based on the EIS measurement, and diagnose the battery cell based on the slope.

9. The apparatus of claim 8, wherein the processor diagnoses the battery cell as a defective cell when the slope is equal to or less than a threshold value.

10. The apparatus of claim 9, wherein the threshold value is −8.2.

11. The apparatus of claim 9, wherein the threshold value is −8.

12. The apparatus of claim 8, wherein the predetermined frequency is equal to or less than 25 Hz.

13. The apparatus of claim 12, wherein the predetermined frequency is equal to or greater than 1 Hz.

14. The apparatus of claim 8, wherein the voltage section includes a section between 3.5V and 3.8V.

15. The apparatus of claim 8, further comprising:
a memory configured to store information on a reactance slope of a normal cell and a reactance slope of a defective cell for each frequency,
wherein the processor:
obtains information on the reactance slope of the normal cell and the reactance slope of the defective cell corresponding to the predetermined frequency from the memory,
diagnoses the battery cell as a normal cell when the reactance slope in the voltage section of the predetermined range is included in the reactance slope of the normal cell, and
diagnoses the battery cell as a defective cell when the reactance slope in the voltage section of the predetermined range is included in the reactance slope of the defective cell.

16. A computer program stored in a non-volatile recording medium, and when executed by a computing device, causing the computing device to execute a method comprising:
an operation of calculating a slope of a reactance of a battery cell in a voltage section of a predetermined range based on an electrochemical impedance spectroscopy (EIS) measurement performed in a charging section of an activation process for applying an activation waveform with a predetermined frequency to the battery cell, and
an operation of diagnosing the battery cell based on the slope.
